(19) United States
(12) Patent Application Publication
(10) Pub. No.: US 2017/0362366 A1
(43) Pub. Date: Dec. 21, 2017

(54) POLYMERIZABLE COMPOSITION AND USES OF THE SAME

(71) Applicant: ETERNAL MATERIALS CO., LTD., Kaohsiung City (TW)

(72) Inventors: Joshua LAI, Kaohsiung City (TW); Hong-Zhang CHEN, Kaohsiung City (TW); Tu-Yi WU, Kaohsiung City (TW)

(21) Appl. No.: 15/398,359

(22) Filed: Jan. 4, 2017

(30) Foreign Application Priority Data
Jun. 17, 2016 (TW) 105119129

(51) Int. Cl. C08F 257/02; G03F 7/20; G03F 7/029; B41C 1/10; G03F 7/038; G03F 7/033; G03F 7/32; G03F 7/16

(52) U.S. Cl. CPC C08F 257/02; G03F 7/32; G03F 7/2004; G03F 7/168; B41C 1/10; G03F 7/038; G03F 7/033; G03F 7/029; G03F 7/16

(57) ABSTRACT

A polymerizable composition is provided, including an infrared absorber, a polymerization initiator, a polymerizable compound, and a polymer binder, wherein the polymer binder is a particulate random copolymer, and the polymer binder has structural units derived from a polymerizable polyalkylene oxide-based monomer and a polymerizable nitrogen-free non-polyalkylene oxide-based monomer. The polymerizable composition may be used in the production of imageable elements or printing plates.

### CLAIM FOR PRIORITY

This application claims the benefit of Taiwan Patent Application No. 105119129 filed on Jun. 17, 2016, the subject matters of which are incorporated herein in their entirety by reference.

### BACKGROUND

### Field of the Invention

The present invention provides a polymerizable composition and uses of the same. In particular, the present invention relates to a polymerizable composition using a specific particulate random copolymer as a polymer binder, and uses of the polymerizable composition in producing imageable elements and printing plates.

### Descriptions of the Related Art

Printing is a process for directly or indirectly transferring text and images onto the surface of a medium to be printed through a printing plate. Printing processes may be roughly classified into the following categories: gravure printing, relief printing, screen printing, and planographic printing.

Common planographic printing processes include presensitized plate (PS) printing and computer to plate (CTP) printing. Recently, CTP printing has almost completely replaced conventional PS printing because the heat source in the CTP printing is controlled by a computer. As a result, a lithography laboratory and artificial correction of printing plates are not required anymore. Printing plates may be produced in a general room. Furthermore, the plates producing efficiency, output speed, and print run of the CTP printing are all better than those of PS printing.

In general, a printing plate is produced by conducting an imaging process to an imageable element to form desired text and images. For example, a CTP printing plate is usually produced by the following process. An imageable element is provided, which comprises a substrate preferably with a hydrophilic surface. An imageable layer is provided on the substrate, and an imaging area and a non-imaging area are defined on the imageable layer. If the imageable layer is a negative photosensitive layer, the imaging area is exposed to light to form a latent image. The imageable layer comes into contact with a development solution to selectively remove the imageable layer in the non-imaging area from the surface of the substrate to form text and images. The imageable element with text and images is rinsed with a fountain solution to form a hydrophilic layer on the surface of the substrate on which the non-imaging area of the imageable layer was positioned to finish the production of the printing plate.

In the production of the CTP printing plate, a thermal sensitive imaging paste solution is used. The thermal sensitive imaging paste solution may be classified into two categories, i.e., positive thermal sensitive imaging paste solution and negative thermal sensitive imaging paste solution. In the case of a positive thermal sensitive imaging paste solution, the heated portion of the positive thermal sensitive imaging paste solution is dissoluble in a development solution, while the non-heated portion of the positive thermal sensitive imaging paste solution is not dissoluble in the development solution. In the case of a negative thermal sensitive imaging paste solution, the heated portion of the negative thermal sensitive imaging paste solution generates a cross linkage that increases the structural strength and is therefore not dissoluble in a development solution, while the non-heated region of the negative thermal sensitive imaging paste solution is dissoluble in the development solution.

In addition, development solutions are usually strong alkaline aqueous solutions or contain a substantial amount of organic solvents. Therefore, the subsequent disposal of development solutions is costly and environmentally unfriendly. In view of this, a new development technique for negative thermal sensitive imaging paste solutions, called “on-press” technique, has been developed. According to the “on-press” technique, an imageable element is directly arranged on a printer, and the imageable element is developed by coming into contact with ink and/or a fountain solution during the initial printing operations to produce a printing plate. In other words, according to the “on-press” technique, the imageable element after being exposed to light is directly treated with a fountain solution to finish the development and rinsing processes without using a development solution.

The present invention provides a polymerizable composition, which is useful in providing the negative imageable layer of an imageable element. The imageable element that is produced using the polymerizable composition could be developed via a fountain solution, while the printing plate that is produced from the imageable element could meet relevant development standards and has outstanding durability.

### SUMMARY

An objective of the present invention is to provide a polymerizable composition, comprising:
an infrared absorber;
a polymerization initiator;
a polymerizable compound; and
a polymer binder,
wherein the polymer binder is a particulate random copolymer and comprises structural units derived from a polymerizable polyalkylene oxide-based monomer and a polymerizable nitrogen-free non-polyalkylene oxide-based monomer.

Another objective of the present invention is to provide a negative imaging paste solution, comprising the above described polymerizable composition and a solvent.

Yet another objective of the present invention is to provide an imageable element, comprising the following components:
a substrate; and
an imageable layer on the substrate,
wherein the imageable layer is formed by coating the above described negative imaging paste solution on the substrate.

Still another objective of the present invention is to provide a method of producing a printing plate, comprising the following steps:
(i) providing the above described imageable element, and defining an imaging area and a non-imaging area on the imageable layer of the imageable element;
(ii) exposing the imageable layer in the imaging area to near infrared radiation to form a latent image; and
(iii) after step (ii), contacting the imageable layer with fountain solution to selectively remove the imageable layer in the non-imaging area from the substrate.

The present invention has evident advantages and beneficial effects compared to prior art. The polymerizable composition of the present invention is useful in the production of a negative printing plate. The present invention includes the following features:
The present invention uses a particulate random copolymer which comprises structural units derived from specific monomers as a polymer binder, and the imageable element prepared therefrom could be provided with good smoothness and film formability.
The present invention has advantages of simple production and low cost compared to a polymerizable composition that uses a grafting copolymer or block copolymer as a polymer binder.
The polymerizable composition of the present invention may be used as an imageable material of an imageable element, and the development and rinsing processes of the imageable element can be directly done via a fountain solution after light exposure process of the imageable element. The text and image structures of the imageable element formed thereby meet relevant development standards and have advantages such as good solvent resistance, good adhesion force to the substrate, and high resolution, and therefore print run is improved and printing cost is lowered.

To render the above objectives, technical features and advantages of the present invention more apparent, the present invention will be described in detail with reference to some embodiments hereinafter.

### DESCRIPTION OF THE PREFERRED EMBODIMENT

Hereinafter, some embodiments of the present invention will be described in detail. However, without departing from the spirit of the present invention, the present invention may be embodied in various embodiments and should not be limited to the embodiments described in the specification. Unless it is additionally explained, the expressions “a,” “the,” or the like recited in the specification (especially in the claims) should include both the singular and the plural forms. Furthermore, unless it is additionally explained, when describing the constituents of a solution, mixture or composition in the specification, the amount of each constituent is calculated based on the non-volatiles (NV). i.e., regardless of the weight of the solvent.

Polymerizable Composition

The present invention provides a polymerizable composition useful in the production of a negative printing plate. One technical feature of the present invention lies in using a particulate random copolymer as a polymer binder, wherein the random copolymer comprises structural units derived from specific monomers (polymerizable polyalkylene oxide-based monomers and polymerizable nitrogen-free non-polyalkylene oxide-based monomers). The present invention has advantages such as a simple production and low cost compared to a polymerizable composition that uses a grafting copolymer or block copolymer as a polymer binder. Furthermore, the polymerizable composition of the present invention may be used as an imageable layer material of an imageable element. The development and rinsing processes of the imageable element prepared using the polymerizable composition of the present invention could be done via a fountain solution. The text and image structures of the printing plate produced from the imageable element of the present invention could meet relevant development standards and have advantages such as good solvent resistance, good adhesion force to the substrate, and high resolution. Therefore, print run could be improved and printing costs could be lowered.

Specifically, the polymerizable composition of the present invention comprises an infrared absorber, a polymerization initiator, a polymerizable compound, and a polymer binder, wherein the polymer binder is a particulate random copolymer and comprises structural units derived from a polymerizable polyalkylene oxide-based monomer and a polymerizable nitrogen-free non-polyalkylene oxide-based monomer. Based on the total weight of the polymerizable composition, the amount of infrared absorber is about 0.125 wt % to about 2.0 wt %, the amount of the polymerization initiator is about 0.25 wt % to about 12.5 wt %, the amount of the polymerizable compound is about 12.5 wt % to about 40 wt %, and the amount of the polymer binder is about 10 wt % to about 85 wt %.

Hereinafter, detailed descriptions will be provided for each component of the polymerizable composition, respectively.

[Infrared Absorber]

The infrared absorber refers to an absorber which can absorb infrared radiation with a wavelength from about 800 nm to about 1200 nm. The infrared absorber absorbs light radiation and converts the absorbed light radiation into heat and thus, is also called “photothermal conversion material”.

One embodiment of suitable infrared absorbers is a pigment. Examples of the pigment include carbon black, Heliogen Green, Nigrosine Base, iron(III) oxide, manganese oxide, Prussian Blue, and Paris blue. The particle size of the pigment is preferably not more than the thickness of the layer which the pigment applies to, and more preferably not more than half of the thickness of the said layer.

Another embodiment of suitable infrared absorbers is a dye with an appropriate absorption spectrum and solubility, preferably with a high extinction coefficient ranging from 750 nm to 1200 nm. Examples of the dye include methine, polymethine, arylmethine, cyanine, hemicyanine, streptocyanine, squarylium, pyrylium, oxonol, naphthoquinone, anthraquinone, porphyrin, azo, croconium, triarylamine, thiazolium, indolium, oxazolium, indocyanine, indotricarbocyanine, oxatricarbocyanine, phthalocyanine, thiocyanine, thiatricarbocyanine, merocyanine, cryptocyanine, naphthalocyanine, polyaniline, polypyrrole, polythiophene, chalcogenopyryloarylidene, bis(chalcogenopyrylo)polymethine, oxyindolizine, pyrazoline azo, and oxazine.

In some embodiments of the present invention, it is preferable to use a hydrophilic infrared absorber. Examples of the hydrophilic infrared absorber include cyanine dyes with one or more sulfate groups and/or sulfonate groups. In the appended examples, a hydrophilic cyanine dye is used as the infrared absorber.

In the polymerizable composition of the present invention, the amount of the infrared absorber is not particularly limited, as long as the infrared absorber can provide the desired light radiation conversion. In general, based on the total weight of the polymerizable composition, the amount of the infrared absorber may be about 0.125 wt % to about 2.0 wt %, such as 0.2 wt %, 0.25 wt %, 0.3 wt %, 0.5 wt %, 0.75 wt %, 1 wt %, 1.25 wt %, 1.5 wt %, or 1.75 wt %.

[Polymerization Initiator]

The polymerization initiator is used to initiate the polymerization reaction of the polymerizable compound and the polymer binder during the light exposure process of an imageable element. In general, the polymerization initiator generates radicals when exposed to heat or electromagnetic radiations. The generated radicals will initiate the polymerization reaction. Therefore, the polymerization initiator is also called a “free radical generator.” Examples of suitable electromagnetic radiation include ultraviolet, visible light, infrared, and the like, corresponding to a spectrum range of about 300 nm to about 1400 nm. In some embodiments of the present invention, the polymerization initiator is a thermal sensitive polymerization initiator, which generates radicals via the heat that is generated by converting the infrared through the infrared absorber. Examples of thermal sensitive polymerization initiators include: peroxides, such as benzoyl peroxide; hydroperoxides, such as cumyl hydroperoxide; azo compounds, such as azo bis-isobutyronitrile; 2,4,5-triaryl imidazolyl dimers (hexaarylbisimidazole); trihalomethyl triazine; borates; onium salts, such as diazonium salt, iodonium salt, sulfonium salt, phosphonium salt, and pyridinium salt; and mixtures thereof. In some embodiments of the present invention, the polymerization initiator is selected from onium salts.

In the polymerizable composition of the present invention, the amount of the polymerization initiator is not particularly limited, as long as the polymerization initiator can initiate the polymerization reaction of the polymerizable compound and the polymer binder. In general, based on the total weight of the polymerizable composition, the amount of the polymerization initiator may be about 0.25 wt % to about 12.5 wt %, such as 0.5 wt %, 1 wt %, 2 wt %, 2.5 wt %, 5 wt %, 7 wt %, 9 wt %, 10 wt %, or 12 wt %.

[Polymerizable Compound]

The main materials of the imageable layers of imageable elements are the polymerizable compound and the polymer binder. The polymerizable compound refers to a compound which may be polymerized or cross-linked by the polymerization initiator, such as, but not limited to, an alkenyl-containing unsaturated compound or an isocyanate-based compound. Suitable polymerizable compounds are usually multifunctional compounds. Examples of polymerizable compounds include those selected from the group consisting of multifunctional acrylate-based compounds, such as diacrylate-based compounds, triacrylate-based compounds, tetraacrylate-based compounds, pentaacrylate-based compounds, hexaacrylated-based compounds, epoxy acrylate-based compounds, polyester acrylate-based compounds, or polyether acrylate-based compounds; multi-isocyanate-based compounds, such as diisocyanate-based compounds, triisocyanate-based compounds, or tetraisocyanate-based compounds; multi-allyl-based compounds, such as diallyl ester-based compounds, triallyl ester-based compounds, or tetraallyl ester-based compounds; and combinations thereof. In some embodiments of the present invention, the polymerizable compound is selected from the group consisting of pentaerythritol triacrylate, pentaerythritol tetraacrylate, dipentaerythritol pentaacrylate, dipentaerythritol hexaacrylate, and combinations thereof.

In the polymerizable composition of the present invention, the amount of the polymerizable compound may be adjusted depending on the needs, with the proviso that the polymerizable compound may form an imaging area that is not dissoluble in a fountain solution together with the polymer binder after the light exposure and development processes. In general, based on the total weight of the polymerizable composition, the amount of the polymerizable compound may be about 12.5 wt % to about 40 wt %, such as 15 wt %, 20 wt %, 25 wt %, 30 wt %, or 35 wt %.

[Polymer Binder]

The polymer binder may be brought into a polymerization reaction or a cross-link reaction to be combined with each other or with the polymerizable compound via the polymerization initiator and light exposure process. The polymer binder used in the present invention is a random copolymer which comprises a structural unit derived from a polymerizable polyalkylene oxide-based monomer and a polymerizable nitrogen-free non-polyalkylene oxide-based monomer. Specifically, the polymer binder is a particulate random copolymer which has a hydrophobic main chain, a polyalkylene oxide segment-containing side group connected to the main chain, and a nitrogen-free side group connected to the main chain. Without being restricted by any theories, it is believed that the feature of having both the hydrophobic main chain and the hydrophilic polyalkylene oxide segment-containing side group is advantageous to the development of an imageable element.

The hydrophobic main chain of the polymer binder may be a full-carbon chain or a heteroatom-containing carbon chain. For example, if the polymer binder is obtained from the polymerization of ethylenically unsaturated monomers, the hydrophobic main chain may be a full-carbon chain. If the polymer binder is obtained from the condensation polymerization of monomers, the hydrophobic main chain may be a heteroatom-containing carbon chain.

The hydrophilic polyalkylene oxide segment-containing side group of the polymer binder is derived from a polymerizable polyalkylene oxide-based monomer. For example, the polymerizable polyalkylene oxide-based monomer may be an ethylenically unsaturated monomer containing a polyalkylene oxide segment of the following formula (1). In the formula (1), R is benzyl or a C₁ to C₆ alkyl, such as methyl, ethyl, n-propyl, iso-propyl, n-butyl, sec-butyl, iso-butyl, t-butyl, n-pentyl, iso-pentyl, neo-pentyl, n-hexyl, iso-hexyl, 1,1-dimethyl-butyl, 2,2-dimethyl-butyl, cyclopentyl, or cyclohexyl; x is an integer from 1 to 3; and y is an integer from 5 to 150. Preferably, x is an integer from 2 to 3, and y is an integer from 10 to 150.

—(O—(CH₂)ₓ)_{y}—OR formula (1)

In some embodiments of the present invention, the polymerizable polyalkylene oxide-based monomer is a polymerizable polyalkylene oxide-based monomer with at least one carbamate group. The polymerizable polyalkylene oxide-based monomer with at least one carbamate group may be an ethylenically unsaturated monomer containing a polyalkenyl oxide segment of the following formula (2), wherein R, x, and y in formula (2) have the same definition as those in formula (1).

—NC(═O)—(O—(CH₂)ₓ)_{y}—OR formula (2)

In some embodiments of the present invention, the polymerizable polyalkylene oxide-based monomer is an ethylenically unsaturated monomer of the following formula (3), wherein t is 0 or 1, z is an integer from 1 to 20, G is —C(═O)—O—, —O—, or —CH2-, and Y has a structure of formula (2).

(CH₂═CHₜ(CH₃)₁₋ₜ))-G-(CH₂)_{z}—Y formula (3)

The nitrogen-free side group of the polymer binder is derived from a polymerizable nitrogen-free non-polyalkylene oxide-based monomer. In some embodiments of the present invention, the polymerizable nitrogen-free non-polyalkylene oxide-based monomer is an ethylenically unsaturated nitrogen-free non-polyalkylene oxide-based monomer. Examples of the ethylenically unsaturated nitrogen-free non-polyalkylene oxide-based monomer include styrene-based monomers, alkyl vinyl ethers, alkyl vinyl esters, and combinations thereof. In some embodiments of the present invention, the polymerizable nitrogen-free non-polyalkylene oxide-based monomer is selected from styrene-based monomers.

The term “styrene-based monomer” refers to styrene and derivatives of styrene. Examples of styrene-based monomers include styrene, 4-chloro-α-methylstyrene, α-methyl styrene, 4-methyl styrene, α-ethyl styrene, 4-ethyl styrene, 3-methyl styrene, 4-propyl styrene, 4-cyclohexyl styrene, divinyl benzene, fluorostyrene, bromostyrene, chlorostyrene, chloromethyl styrene, 4-methoxy styrene, 4-ethoxy styrene, hydroxystyrene, acetoxystyrene, 1-vinylnaphthalene, 2-vinylnaphthalene, 4-dodecyl styrene, 2-ethyl-4-phenylmethyl styrene, 4-(phenylbutyl)styrene, and combinations thereof. The styrene-based monomer is preferred to be selected from the group consisting of styrene, α-methyl styrene, 4-methyl styrene, α-ethyl styrene, 4-ethyl styrene, 3-methyl styrene, 4-propyl styrene, 4-dodecyl styrene, 4-methoxy styrene, 4-ethoxy styrene, and combinations thereof. In the appended examples, the styrene-based monomer is styrene.

Examples of alkyl vinyl ethers include linear alkyl vinyl ethers, branched alkyl vinyl ethers, cycloalkyl vinyl ethers, hydroxy alkyl vinyl ethers, and combinations thereof. The alkyl in the alkyl vinyl ethers is preferred to be a C₁ to C₁₈ alkyl, and examples of such alkyl vinyl ethers include, but are not limited to, methyl vinyl ether, ethyl vinyl ether (EVE), and allyl vinyl ether.

Examples of alkyl vinyl esters include linear alkyl vinyl esters, branched alkyl vinyl esters, cycloalkyl vinyl esters, hydroxy alkyl vinyl esters, and combinations thereof. The alkyl in the alkyl vinyl ester is preferred to be a C₁ to C₁₈ alkyl, and examples of such alkyl vinyl esters include, but are not limited to, methyl vinyl ester, ethyl vinyl ester, allyl vinyl ester, vinyl versatate, and vinyl acetate (Vac).

In some embodiments of the present invention, the polymer binder is synthesized by using the polymerizable polyalkylene oxide-based monomer and the polymerizable nitrogen-free non-polyalkylene oxide-based monomer in the following ratio: the amount of the polymerizable polyalkylene oxide-based monomer is about 5 wt % to about 40 wt % based on the total weight of the polymerizable polyalkylene oxide-based monomer and the polymerizable nitrogen-free non-polyalkylene oxide-based monomer. However, the monomers may be used in different ratios.

The polymer binder in the polymerizable composition of the present invention is a particulate random copolymer. The term “particulate” refers to a discrete particle type in which the particles do not tend to agglomerate or combine to form a continuous film under ordinary physical processing conditions. The number average diameter of particles may range between 100 nm and 500 nm, and preferably between 150 nm and 250 nm. The weight average molecular weight (Mw) of the polymer binder is usually between 20,000 and 200,000, and preferably between 50,000 and 100,000. Without being restricted by any theories, it is believed that the polymer binder in the form of (discrete) particles could improve the outcome of the development of imagable elements. In particular, it is believed that using the polymer binder in the form of nano-sized particles could further improve the smoothness of the imageable elements and the resolution of the printing plate.

In the polymerizable composition of the present invention, one or more polymer binders conforming to the aforementioned conditions may be used. In addition, the amount of the polymer binder may be adjusted depending on the needs, with the proviso that the polymer binder could form the desired text and image structure together with the polymerizable compound after the light exposure and development processes. In general, based on the total weight of the polymerizable composition, the amount of the polymer binder may be about 10 wt % to about 85 wt %, such as a range from 15 wt % to 75 wt %, from 30 wt % to 75 wt %, from 35 wt % to 75 wt %, or from 35 wt % to 60 wt %. If the amount of the polymer binder is less than 10 wt/o, the film formability of the polymerizable composition is poor, and the ink receptivity and abrasion resistance of the printing plate produced using the polymerizable composition are poor. If the amount of the polymer binder is higher than 85 wt %, the development ability of the printing plate produced using the polymerizable composition is deteriorated, and the printing plate cannot be effectively developed.

One or more additives known by persons with ordinary skill in the art may be optionally added into the polymerizable composition of the present invention, and examples of the additive include, but are not limited to, co-binders, and inorganic fillers.

Co-binders are usually water-soluble or water-dispersible polymers. Examples of co-binders include: cellulose derivatives, such as carboxymethyl cellulose, methylcellulose, hydroxypropyl methylcellulose, hydroxypropyl cellulose, hydroxyethyl cellulose; polyvinyl alcohol; polyacrylic acid; polymethacrylic acid; polyvinyl pyrrolidone; polylactide; polyvinyl phosphonic acid; synthetic co-polymers, such as a copolymer of an alkoxy polyethylene glycol acrylate (or methacrylate), e.g., methoxy polyethylene glycol acrylate (or methacrylate), and a monomer selected from methyl methacrylate, methyl acrylate, butyl methacrylate, butyl acrylate, and allyl methacrylate; and mixtures thereof. Co-binders may provide a crosslinkable site, for example, an ethylenically unsaturated site.

To improve the development speed, one or more inorganic fillers may be optionally added into the polymerizable composition. Examples of inorganic fillers suitable for the present invention include those known by persons with ordinary skill in the art. For example, the inorganic filler may be selected from the group consisting of, but are not limited to, silica, aluminum oxide, magnesium oxide, magnesium hydroxide, calcium carbonate, talc, clays, aluminum nitride, boron nitride, aluminum hydroxide, silicon aluminum carbide, silicon carbide, sodium carbonate, titanium dioxide, zinc oxide, zirconium oxide, quartzs, graphites, calcined kaolin, pryan, micas, hydrotalcite, hollow silica, glass beads, ceramic whiskers, carbon nanotubes, and combinations thereof. The inorganic filler is preferred to be magnesium oxide, silica, zirconium oxide, titanium dioxide, or a mixture thereof. In addition, the specific surface area of the inorganic filler preferably ranges from about 100 m²/g to about 250 m/g, and more preferably from about 150 m²/g to about 200 m²/g. The inorganic filler may further improve the on-press development speed of imageable elements. In general, based on the total weight of the polymerizable composition, the amount of the inorganic filler is about 0.1 wt % to about 10 wt %, and preferably about 0.5 wt % to about 5 wt %.

Negative Imaging Paste Solution

The polymerizable composition of the present invention may be used in a negative imaging paste solution for preparing an imageable element that is used for the production of a printing plate. Thus, the present invention also provides a negative imaging paste solution, which comprises the polymerizable composition of the present invention and a solvent, wherein the solvent is used for adjusting the viscosity of the negative imaging paste solution to a range suitable for the relevant operations. The solvent may be added during the formulation of the polymerizable composition or right before use. According to an embodiment of the present invention, a portion of solvent is added during the formulation of the polymerizable composition to obtain a negative imaging paste solution, and after the formulation, another portion of solvent is added into the negative imaging paste solution to adjust the viscosity. After the viscosity adjustment, the amount of non-volatile components in the negative imaging paste solution ranges from about 5 wt % to about 30 wt %. The solvent may be any inert organic solvent which can dissolve (or disperse) but not react with the components of the polymerizable composition of the present invention and does not have an unfavorable effect on the polymerization reaction of the polymerizable composition. For example, a suitable solvent may be selected from the group consisting of water, esters, ketones, alcohols, ethers, lactams, and combinations thereof. Examples of water include, but are not limited to, pure water and deionized water. Examples of esters include, but are not limited to, ethyl acetate and butyl acetate. Examples of ketones include, but are not limited to, methyl ethyl ketone, methyl isobutyl ketone, methyl propyl ketone and acetone. Examples of alcohols include, but are not limited to, methanol, ethanol, n-propyl alcohol, isopropyl alcohol, and butanol. Examples of ethers include, but are not limited to, propyl ether, butyl ether, ethylene glycol methyl ether, and propylene glycol methyl ether. Examples of lactams include, but are not limited to, N-methyl pyrrolidone and N-ethyl pyrrolidone. In some embodiments of the present invention, the solvent is selected from the group consisting of deionized water, n-propyl alcohol, methyl ethyl ketone (MEK), propylene glycol methyl ether (PM), and mixtures thereof. The aforementioned negative imaging paste solution may be prepared by any processes that are known to persons with ordinary skill in the art. For example, the negative imaging paste solution may be prepared by evenly mixing the components of the polymerization composition of the present invention through a stirrer and then dissolving or dispersing the obtained mixture into a solvent.

Imagable Element

The negative imaging paste solution of the present invention may be used for preparing an imageable element for producing a printing plate. Thus, the present invention also provides an imageable element, which comprises a substrate and an imageable layer on the substrate, wherein the imageable layer is formed by coating the negative imaging paste solution of the present invention on the substrate. In the imageable element of the present invention, the substrate may be any substrate that is known to be suitable for preparing a planographic printing plate. In general, the substrate is strong, stable, and flexible. For example, the substrate may be a polymer substrate, a ceramic substrate, a metal substrate (e.g., an aluminum substrate, a zinc substrate, a titanium substrate, or an alloy substrate made of the aforementioned metals), or a paper substrate. The substrate may have an integrated structure or a laminated structure. In addition, the substrate usually has a hydrophilic surface, so that fountain solution may attach to the surface of the substrate after the development process. A hydrophilic surface may be provided by any conventional surface treatment techniques, such as a physical graining treatment, an electrochemical graining treatment, a chemical graining treatment, an anodizing treatment or a sealing treatment. In the preferred embodiment of the present invention, the substrate is a hydrophilic aluminum substrate.

The imageable layer on the substrate may be formed by any conventional coating method. For example, the imageable layer may be formed by coating the negative imaging paste solution of the present invention onto the surface of the substrate by means of a spin coating method, bar coating method, gravure coating method, slot coating method, roller coating method, or die coating method, and then performing an appropriate drying treatment. Suitable drying methods include, but are not limited to, oven drying method, air drying method, and air blasting drying method.

In some embodiments of the present invention, a functional coating may be inter-disposed between the substrate and the imageable layer. The functional coating may be, for example, a development improving layer for improving the outcome of development, or a heat insulation layer for providing a heat insulation effect for the imaging exposure area. In some embodiments of the present invention, a functional coating may be further provided on the imageable layer. The functional coating may be, for example, a cover layer for preventing the diffusion of oxygen into the imageable layer during the storage of the imageable element. Applications of the aforementioned coatings may be accomplished by persons with ordinary skill in the art based on their ordinary skill and the disclosure of the subject specification, and thus the detailed description for these applications is omitted here.

Method of Producing Printing Plate

The imageable element of the present invention may be used for producing a printing plate. Thus, the present invention also provides a method of producing a printing plate, and the method comprises (i) providing an imageable element as described above, and defining an imaging area and a non-imaging area on the imageable layer of the imageable element; (ii) exposing the imageable layer in the imaging area to near infrared radiation, to form a latent image; and (iii) after step (ii), contacting the imageable layer with fountain solution to selectively remove the imageable layer in the non-imaging area from the substrate

In step (i), an imaging area and a non-imaging area are defined in the imageable layer according to the text and images to be printed. For example, the imaging area and the non-imaging area may be defined by placing a mask produced according to the text and images to be printed on the imageable layer. Alternatively, one may set the text and images to be printed in a computer and then control the irradiation area of the near infrared radiation in step (ii).

In step (ii), any device that is capable of emitting near infrared radiation may be used, such as an infrared light emitting diode (LED) laser. When the imaging area is irradiated by the near infrared radiation, a polymerization reaction or a cross-link reaction will be initiated, and consequently the latent image of the text and images to be printed will be provided.

In step (iii), the imageable layer in the non-imaging area is removed by fountain solution. The fountain solution may be any conventional fountain solution in the art. In general, a fountain solution is an aqueous solution comprising components such as a desensitizer, pH adjuster, buffering agent, bactericide, mildew proof agent, wetting agent, and solvent. Examples of solvent include water, alcohols (e.g., isopropyl alcohol or ethanol), ethers (e.g., diethyl ether or ethylene glycol monomethyl ether), and mixtures thereof.

In the imageable layer formed by the polymerizable composition of the present invention, the non-imaging area that is not exposed to the near infrared radiation in step (ii) may be easily removed by a fountain solution. The development outcome of the imageable element of the present invention meet relevant development standards. The text and images structures formed in the imaging area have advantages such as good solvent resistance, good fountain solution resistance, good adhesion force to substrate, and high resolution, and consequently, the printing plate produced by the present invention could improve the print run and lower the printing cost.

The present invention will be further illustrated by the embodiments hereinafter, wherein the measuring instruments and methods are respectively as follows:

[Imageable Element Appearance Evaluation]

The surface of the imageable element was checked with unaided eyes for irregular bumps or indentations. If irregular bumps or indentations were found on the surface of the imageable element, the surface was deemed rough. Afterwards, the imageable element was exposed by a SCREEN 8600 exposure machine. The exposure machine could automatically check if the flatness of the imageable element meets the standard requirements of the industry. Therefore, if the imageable element can be imported, exposed, and exported successfully, it means that the flatness of the imageable element meets the standard requirements of the industry, and the appearance evaluation was recorded as “flat”. On the contrary, if the imageable element cannot be imported, exposed, and exported successfully, the appearance evaluation was recorded as “uneven”.

[Exposure Contrast Test]

After the imageable element is exposed by using the SCREEN 8600 exposure machine under 150 mJ/cm², the values of L, a*, and b* in the non-exposed area (0% dot area) and the exposed area (100% dot area) were measured by a HunterLab ColorQuest XE spectrophotometer, respectively. Ten points in each area were selected and measured, the measured values were recorded and averaged, and ΔE was calculated according to the following formula:

ΔE=(ΔL²+Δa*²+Δb*²)̂(1/2)

If ΔE≦1.5, the exposure contrast test was recorded as “visible contrast”.

[Low-Chemical Development Test]

Forty kilograms of development solution were formulated by adding water into 1 kilogram of low-chemical development agent “Chang Xian-500S” (Eternal Materials Co., Ltd.) and then added into a PS88BF development machine. An exposed imageable element was put into the development machine for development, wherein the development temperature was 23° C. and the development time was 30 seconds. The outcome of the development was evaluated according to the standards: if the text and images were clear and no imageable layer material remained in the non-imaging area, the low-chemical development test was recorded as “OK”; if the text and images in the imaging area had fractures while no imageable layer material remained in the non-imaging area, the low-chemical development test was recorded as “fracture observed”; if the text and images were unclear and the imageable layer material remained in the non-imaging area, the low-chemical development test was recorded as “Δ” and if the imageable layer material in the non-imaging area could not be removed at all, the low-chemical development test was recorded as “X”.

[On-Press Development Test]

The exposed imageable element was subjected to an on-press development though a XinKaiYuan 47XIII Rapid printer. The steps of the on-press development were as follows: hanging the exposed imageable element, making a water roller and ink roller come into contact with the exposed imageable element simultaneously, and operating the rollers for 5 seconds. If the development was incomplete after the 5 second operation, the operating time was extended to 1 min at most. The development speed was determined by the required operation time. Afterwards, papers were delivered for printing until the fiftieth piece of paper was printed. The on-press development test was evaluated by observing the imaging clarity of the fiftieth piece of paper and the cleanness in the non-imaging area of the fiftieth piece of paper. If the text and images were clear and no ink remained in the non-imaging area, the on-press development test was recorded as “OK”; if the text and images had fractures but no ink remained in the non-imaging area, the on-press development test was recorded as “fracture observed”; if the text and images were unclear and ink remained in the non-imaging area, the on-press development test was recorded as “Δ”; and if the surface of the paper was completely stained with ink, the on-press development test was recorded as “X”.

[20 wt % Isopropyl Alcohol Resistance Test]

The exposed imageable element was developed via a low-chemical development to provide a printing plate. An absorbent gauze was moistened with a 20 wt % isopropyl alcohol solution and then fixed on the head of a reciprocating abrasion tester. The printing plate was fixed on the reciprocating abrasion tester. An abrasion test was performed in 100% dot areas through the reciprocating abrasion tester at a frequency of 60 Hz with a loading of 500 grams. After 1000 times of reciprocating abrasions, the result was evaluated by observing whether the dots wore down or not. If the dots were not worn down, the 20 wt % isopropyl alcohol resistance test was recorded as “OK”; if the dots wore down, the 20 wt % isopropyl alcohol resistance test was recorded as “Δ”; and if the dots wore down to the extent that the bottom of the printing plate was revealed, the 20 wt % isopropyl alcohol resistance test was recorded as “X”.

[Imaging Area Ink Receptivity Test]

The exposed imageable element was developed via a general on-press development to prepare a printing plate. A sample was printed by the printing plate, and the color density of the sample at 1%, 2%, 3%, 4%, 5%, 6%, 7%, and 10% dots were evaluated. If the color densities in the whole areas were visually identifiable with unaided eyes, the imaging area ink receptivity test was recorded as “OK”; if only the color densities in 2% area to 10% area were visually identifiable with unaided eyes, the imaging area ink receptivity test was recorded as “Δ”; and if only the color densities in 3% area to 10% area were visually identifiable with unaided eyes, the imaging area ink receptivity test was recorded as “X”.

[Print Run Test]

Four pieces of imageable elements were subjected to a color-separation exposure process and then subjected to an on-press development by a Komori Lithrone S26 machine, wherein a 5 wt % of isopropyl alcohol aqueous solution as a fountain solution, a soy ink, and simile papers were used. The print run test was performed at a printing speed of 15,000 pieces per minute, and the printed samples were collected at an interval of 5,000 pieces (i.e., collecting the first piece, the 5,000^{th} piece, the 10,000^{th} piece, the 15,000^{th} piece, and so on) until the 100,000^{th} piece was collected. The variations of dot values on the printed samples were measured by a dot measuring device. When the variation of dot values between the measured printed sample and the first piece was more than 0.5%, the printing was stopped and the print run was recorded.

### EXAMPLES

<Preparation of Hydrophilic Monomer HM-400>

400 grams of methoxypolyethylene glycol (Mw=1,000 to 8.000), 0.04 grams of monomethyl ether of hydroquinone (MEHQ), and 0.04 grams of dibutyltin dilaurate were added into a four-necked flask, and the four necks of the four-necked flask were connected to a mechanical stirrer, a temperature probe with a thermometer, a condensation tube, and a feeding funnel with a dry air aeration tube, respectively, 140 grams of 2-isocyanatoethyl acrylate (structure:

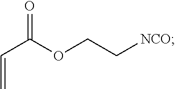

trade name: KarenzAOI, available from Showa Denko) was added into the feeding funnel. The reaction temperature was raised to 60° C., and then 2-isocyanatoethyl acrylate was slowly added dropwise into the reaction flask in 3 hours. After the addition of 2-isocyanatoethyl acrylate was finished, the reaction temperature was controlled at 60° C. and the obtained mixture was stirred for 3 hours. After that, the reaction was checked for completion as determined by the disappearance of a 2270 cm⁻¹ signal as measured by an infrared spectrophotometer. After completion, the product was poured into a polypropylene (PP) vessel and capped for preservation.

<Preparation of Polymer Binder>

During the preparation of the polymer binder, a solvent may be optionally used to make the polymer binder suitable for subsequent operations. In general, the ratio of non-volatiles is about 10 wt % to 50 wt % based on the total weight of the polymer binder. The solvent may be selected from the group consisting of water, esters, ketones, alcohols, ethers, lactams, or combinations thereof. In the following preparation examples of the polymer binder, the percentage of non-volatiles in the polymer binder is 25 wt %.

### Preparation Example 1: Polymer Binder SU-1000

80 grams of hydrophilic monomer HM-400, 120 grams of styrene, 5 grams of azobisisobutyronitrile (AIBN), 500 grams of n-propyl alcohol, and 100 grams of deionized water (DI water) were added into a four-necked flask, and the four necks of the four-necked flask were connected to a mechanical stirrer, a temperature probe with a thermometer, a condensation tube, and a feeding funnel with a dry nitrogen aeration tube, respectively. The reaction temperature was raised to 80° C., and the obtained mixture was stirred for 8 hours. The reaction was checked for completion as determined by the disappearance of unreacted styrene as measured by a gas chromatograph. If unreacted styrene remained, the reaction time was prolonged, and after another 3 hours, the residue amount of styrene was measured again. After completion, the temperature was lowered to room temperature, and particulate Polymer binder SU-1000 was obtained. Polymer binder SU-1000 was poured into a PP vessel and capped for preservation. The main peak of the molecular weight of polymer binder SU-1000 was 63,000 as measured by a gel permeation chromatograph (GPC).

### Preparation Example 2: Polymer Binder SU-1001

The preparation procedures of Preparation Example 1 were repeated to prepare polymer binder SU-1001, except that the amount of hydrophilic monomer HM-400 was adjusted to be 50 grams, and the amount of styrene was adjusted to be 150 grams. The main peak of the molecular weight of polymer binder SU-1001 was 68,000 as measured by the GPC.

### Preparation Example 3: Polymer Binder SU-1002

The preparation procedures of Preparation Example 1 were repeated to prepare polymer binder SU-1002, except that the amount of hydrophilic monomer HM-400 was adjusted to be 30 grams, and the amount of styrene was adjusted to be 170 grams. The main peak of the molecular weight of polymer binder SU-1002 was 71,000 as measured by the GPC.

### Preparation Example 4: Polymer Binder SU-1003

The preparation procedures of Preparation Example 1 were repeated to prepare polymer binder SU-1003, except that the amount of hydrophilic monomer HM-400 was adjusted to be 10 grams, and the amount of styrene was adjusted to be 190 grams. The main peak of the molecular weight of polymer binder SU-1003 was 80,000 as measured by the GPC.

### Comparative Preparation Example 1: Comparative Polymer Binder SU-2000

80 grams of hydrophilic monomer HM-400, 60 grams of styrene, 60 grams of acrylonitrile, 5 grams of AIBN, 500 grams of n-propyl alcohol, and 100 grams of deionized water were added into a four-necked flask, and the four necks of the four-necked flask were connected to a mechanical stirrer, a temperature probe with a thermometer, a condensation tube, and a feeding funnel with a dry nitrogen aeration tube, respectively. The reaction temperature was raised to 80° C., and the obtained mixture was stirred for 8 hours. The reaction was checked for completion as determined by the disappearance of unreacted styrene as measured by a gas chromatograph. If unreacted styrene remained, the reaction time was prolonged, and after another 3 hours, the residue amount of styrene was measured again. After completion, the temperature was lowered to room temperature, and particulate comparative polymer binder SU-2000 was obtained. Comparative polymer binder SU-2000 was poured into a PP vessel and capped for preservation. The main peak of the molecular weight of comparative polymer binder SU-2000 was 66,000 as measured by GPC.

### Comparative Preparation Example 2: Comparative Polymer Binder SU-3300

The preparation procedures of Comparative Preparation Example 1 were repeated to prepare comparative polymer binder SU-3300, except that n-propyl alcohol and water were substituted with 600 grams of N-ethyl pyrrolidone. The main peak of the molecular weight of comparative polymer binder SU-3300 was 86,000 as measured by the GPC.

### Comparative Preparation Example 3: Comparative Polymer Binder PU-0615 Resin

47.7 grams of bisphenol A bis(2-hydroxyethyl)ether, 2.5 grams of dimethylolpropionic acid, 1.6 grams of dibutyltin dilaurate, 45.6 grams of isophorone diisocyanate (IPDI), 3.8 grams of 3,5-dimethylpyrazole, and 235 grams of ethyl acetate were added into a four-necked flask, and the four necks of the four-necked flask were connected to a mechanical stirrer, a temperature probe with a thermometer, a condensation tube, and a feeding funnel with a dry nitrogen aeration tube, respectively. The reaction temperature was raised to 70° C., and the obtained mixture was stirred for 1 hour. Next, the reaction temperature was raised to 80° C., and then the obtained mixture was stirred for 12 hours. After that, the reaction was checked for completion as determined by the disappearance of a 2270 cm⁻¹ signal as measured by an infrared spectrophotometer. After completion, the reaction temperature was lowered to room temperature, and then 0.8 grams of sodium hydroxide and 8.2 grams of deionized water were added into the reaction product, and the obtained mixture was poured into a PP vessel. The PP vessel was stirred in an ice bath for 3 minutes at a rotation speed of 15,000 rpm via a high speed homogenizer, and then cooled in the ice bath for 1 minute. The abovementioned homogenization step was repeated four times, and an emulsion of comparative polymer binder PU-0615 resin was obtained. The emulsion was subjected to a rotary concentrator to remove ethyl acetate and consequently obtain a stable comparative polymer binder PU-0615 resin. The main peak of the molecular weight of comparative polymer binder PU-0615 resin was 37,000 as measured by the GPC.

<Preparation of Negative Imaging Paste Solutions>

### Example 1

Hydrophilic cyanine dyes (trade name: S-0306, available from FEW Chemicals) as the infrared absorber,

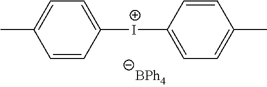

(available from Qiangli Chemical) as the polymerization initiator, dipentaerythritol pentaacrylate (trade name: SR-399, available from Sartomer) as the polymerizable compound, and polymer binder SU-1000 were added into a mixed solvent of PM and MEK (PM:MEK=1:1, wherein PM is propylene glycol methyl ether, and MEK is methyl ethyl ketone). The obtained mixture was stirred to prepare negative imaging paste solution 1 with 225.18 grams of the mixed solvent of PM and MEK. The amount of each constituent is shown in Table 1.

### Example 2

The preparation procedures of Example 1 were repeated to prepare negative imaging paste solution 2, except that 0.36 wt % of silica microsphere particles (trade name: AERODISP® 1030, available from EVONIK) was further added, and the amount of solvent was adjusted as shown in Table 1.

### Example 3

The preparation procedures of Example 1 were repeated to prepare negative imaging paste solution 3, except that polymer binder SU-1000 was substituted by polymer binder SU-1001 as shown in Table 1.

### Example 4

The preparation procedures of Example 1 were repeated to prepare negative imaging paste solution 4, except that polymer binder SU-1000 was substituted by polymer binder SU-1002 as shown in Table 1.

### Example 5

The preparation procedures of Example 1 were repeated to prepare negative imaging paste solution 5, except that polymer binder SU-1000 was substituted by polymer binder SU-1003 as shown in Table 1.

### Example 6

The preparation procedures of Example 1 were repeated to prepare negative imaging paste solution 6, except that dipentaerythritol pentaacrylate was substituted by pentaerythritol triacrylate (trade name: SR-444, available from Sartomer) as the polymerizable compound as shown in Table 1.

### Example 7

The preparation procedures of Example 4 were repeated to prepare negative imaging paste solution 7, except that the weight of the polymer binder was adjusted as shown in Table 1.

### Example 8

The preparation procedures of Example 4 were repeated to prepare negative imaging paste solution 8, except that the weight of the polymer binder was adjusted as shown in Table 1.

### Comparative Example 1

The preparation procedures of Example 1 were repeated to prepare comparative negative imaging paste solution 1, except that the polymerizable compound (i.e., dipentaerythritol pentaacrylate) was not added as shown in Table 1.

### Comparative Example 2

The preparation procedures of Example 1 were repeated to prepare comparative negative imaging paste solution 2, except that polymer binder SU-1000 was substituted by Hybridur 580 binder (available from Air Products) as shown in Table 1.

### Comparative Example 3

The preparation procedures of Example 1 were repeated to prepare comparative negative imaging paste solution 3, except that polymer binder SU-1000 was substituted by comparative polymer binder PU-0615 resin as shown in Table 1.

### Comparative Example 4

The preparation procedures of Example 2 were repeated to prepare comparative negative imaging paste solution 4, except that polymer binder SU-1000 was substituted by comparative polymer binder SU-2000 as shown in Table 1.

### Comparative Example 5

The preparation procedures of Example 1 were repeated to prepare comparative negative imaging paste solution 5, except that polymer binder SU-1000 was substituted by comparative polymer binder SU-3300 as shown in Table 1.

TABLE 1

| | | | | | | | | | | Comp. | Comp. | Comp. | Comp. | Comp. |
|---|---|---|---|---|---|---|---|---|---|---|---|---|---|---|
| Unit: gram | | Ex. 1 | Ex. 2 | Ex. 3 | Ex. 4 | Ex. 5 | Ex. 6 | Ex. 7 | Ex. 8 | Ex. 1 | Ex. 2 | Ex. 3 | Ex. 4 | Ex. 5 |
| Infrared absorber | | 0.32 | 0.32 | 0.32 | 0.32 | 0.32 | 0.32 | 0.32 | 0.32 | 0.32 | 0.32 | 0.32 | 0.32 | 0.32 |
| Polymerizable | SR-399 | 8 | 8 | 8 | 8 | 8 | | 8 | 8 | | 8 | 8 | 8 | 8 |
| compound | SR-444 | | | | | | 8 | | | | | | | |
| Polymerization initiator | | 2.4 | 2.4 | 2.4 | 2.4 | 2.4 | 2.4 | 2.4 | 2.4 | 2.4 | 2.4 | 2.4 | 2.4 | 2.4 |
| Polymer | SU-1000 | 14.3 | 14.3 | | | | 14.3 | | | 14.3 | | | | |
| binder* | SU-1001 | | | 14.3 | | | | | | | | | | |
| | SU-1002 | | | | 14.3 | | | 6 | 30 | | | | | |
| | SU-1003 | | | | | 14.3 | | | | | | | | |
| | Hybridur 580 | | | | | | | | | | 14.3 | | | |
| | PU-0615 | | | | | | | | | | | 14.3 | | |
| | SU-2000 | | | | | | | | | | | | 14.3 | |
| | SU-3300 | | | | | | | | | | | | | 14.3 |

| | | |
|---|---|---|
| Silica microsphere particle | 0.36 | 0.36 |

*the amount of non-volatiles of the polymer binder

<Preparation of Imageable Element>

A hydrophilic aluminum substrate obtained by a degreasing treatment, electrochemical roughening treatment, anodizing treatment and sealing treatment was provided. Negative imaging paste solutions 1 to 8 and comparative negative imaging paste solutions 1 to 5 were coated on a hydrophilic aluminum substrate, respectively. A drying treatment was performed to the coated substrates to provide imageable elements 1 to 8 and comparative imageable elements 1 to 5.

Evaluations of coating appearance, exposure contrast test, low-chemical development test, on-press development test, 20 wt % isopropyl alcohol resistance test, imaging area ink receptivity test, and print run test were carried out. The results are tabulated in Table 2.

TABLE 2

| | | | | | | | | | Comp. | Comp. | Comp. | Comp. | Comp. |
|---|---|---|---|---|---|---|---|---|---|---|---|---|---|
| | Image- | Image- | Image- | Image- | Image- | Image- | Image- | Image- | image- | image- | image- | image- | image- |
| | able | able | able | able | able | able | able | able | able | able | able | able | able |
| | ele- | ele- | ele- | ele- | ele- | ele- | ele- | ele- | ele- | ele- | ele- | ele- | ele- |
| | ment 1 | ment 2 | ment 3 | ment 4 | ment 5 | ment 6 | ment 7 | ment 8 | ment 1 | ment 2 | ment 3 | ment 4 | ment 5 |
| Imageable | flat | flat | flat | flat | flat | flat | flat | flat | flat | flat | uneven | flat | flat |
| element | | | | | | | | | | | | | |
| appearance | | | | | | | | | | | | | |
| evaluation | | | | | | | | | | | | | |
| Exposure | visible | visible | visible | visible | visible | visible | visible | visible | visible | visible | visible | visible | visible |
| contrast test | contrast | contrast | contrast | contrast | contrast | contrast | contrast | contrast | contrast | contrast | contrast | contrast | contrast |
| Low-chemical | ok | ok | ok | ok | ok | ok | ok | ok | fracture | ok | ok | Δ | ok |
| development | | | | | | | | | observed | | | | |
| test | | | | | | | | | | | | | |
| On-press | ok | ok | ok | ok | ok | ok | ok | ok | fracture | ok | ok | ok | Δ |
| development | | | | | | | | | observed | | | | |
| test | | | | | | | | | | | | | |
| On-press | 10 s | 5 s | 10 s | 10 s | 10 s | 10 s | 10 s | 10 s | 10 s | 1 min | 1 min | 30 s | >1 min |
| development | | | | | | | | | | | | | |
| speed | | | | | | | | | | | | | |
| 20 wt % | ok | ok | ok | ok | ok | ok | ok | ok | — | ok | ok | ok | Δ |
| isopropyl | | | | | | | | | | | | | |
| alcohol | | | | | | | | | | | | | |
| resistance. | | | | | | | | | | | | | |
| test | | | | | | | | | | | | | |
| Imaging | ok | ok | ok | ok | ok | ok | ok | ok | — | Δ | ok | Δ | ok |
| area ink | | | | | | | | | | | | | |
| receptivity | | | | | | | | | | | | | |
| test | | | | | | | | | | | | | |
| Print run | 50 | 50 | 51 | 52 | 55 | 40 | 41 | 45 | — | 1 | 0.3 | 2 | 3 |
| (×1,000 pcs) | | | | | | | | | | | | | |

As shown in Table 2, the imageable elements 1 to 8 manufactured by using the polymerizable composition of the present invention meet the development standards (e.g., exposure contrast, low-chemical development, on-press development, and imaging area ink receptivity) and have good solvent resistance and high print run. The durabilities of the printing plates prepared by using the imageable elements of the present invention are significantly improved. Particularly, compared to Example 1, the on-press development speed of the imageable element of Example 2 is further improved by using the inorganic filler (i.e., silica microsphere particles). In addition, Examples 1 and 3 to 5 manifest that the desired inventive efficacy can be provided by using different polymer binders prepared using different ratios of polymerizable polyalkylene oxide-based monomer and polymerizable nitrogen-free non-polyalkylene oxide-based monomer; and Examples 4 and 7 to 8 manifest that the desired inventive efficacy can be provided by using different amounts of polymer binders. Furthermore, Comparative Example 1 indicates that the obtained imageable elements fail to meet the development standards when the negative imaging paste solution does not contain a polymerizable compound; Comparative Examples 2 and 3 indicate that the coating appearance, outcome of development, and print run of the imageable elements are poor when the polymer binder does not belong to the random copolymers as designated by the present invention (e.g., urethane/acrylic acid hybrid binder in Comparative Example 2 or PU binder in Comparative Example 3); and Comparative Examples 4 and 5 indicate that the outcome of development and print run of the imageable elements are poor when the polymer binder comprises cyano.

The examples described above are only for explaining the principle and efficacy of the present invention and illustrating the technical features of the present invention, but not for limiting the scope of the present invention. Any modifications or equal replacements that can be easily accomplished by persons skilled in the art without departing from the principle and spirit of the present invention do not go beyond the protection scope of the present invention. The scope of protection of the present invention should be on the basis of the claims as appended.

What is claimed is:

1. A polymerizable composition, comprising:
an infrared absorber;
a polymerization initiator;
a polymerizable compound; and
a polymer binder, wherein the polymer binder is a particulate random copolymer and comprises structural units derived from a polymerizable polyalkylene oxide-based monomer and a polymerizable nitrogen-free non-polyalkylene oxide-based monomer.

2. The polymerizable composition of claim 1, wherein the polymerizable polyalkylene oxide-based monomer comprises a polyalkylene oxide segment of the following formula (1):
—(O—(CH₂)ₓ)_{y}—OR formula (1),
wherein x is an integer from 1 to 3, y is an integer from 5 to 200, and R is a C₁ to C₆ alkyl or a benzyl.

3. The polymerizable composition of claim 1, wherein the polymerizable polyalkylene oxide-based monomer has at least one carbamate group.

4. The polymerizable composition of claim 2, wherein the polymerizable polyalkylene oxide-based monomer has at least one carbamate group.

5. The polymerizable composition of claim 1, wherein the polymerizable nitrogen-free non-polyalkylene oxide-based monomer is selected from the group consisting of styrene-based monomers, alkyl vinyl ethers, alkyl vinyl esters, and combinations thereof.

6. The polymerizable composition of claim 1, wherein based on the total weight of the polymerizable polyalkylene oxide-based monomer and the polymerizable nitrogen-free non-polyalkylene oxide-based monomer, the ratio of the polymerizable polyalkylene oxide-based monomer is about 5 wt % to about 40 wt %.

7. The polymerizable composition of claim 1, wherein based on the total weight of the polymerizable composition, the amount of the infrared absorber is about 0.125 wt % to about 2.0 wt %, the amount of the polymerization initiator is about 0.25 wt % to about 12.5 wt %, the amount of the polymerizable compound is about 12.5 wt % to about 40 wt %, and the amount of the polymer binder is about 10 wt % to about 85 wt %.

8. The polymerizable composition of claim 7, wherein based on the total weight of the polymerizable composition, the amount of the polymer binder is about 35 wt % to about 75 wt %.

9. A negative imaging paste solution, comprising the polymerizable composition of claim 1 and a solvent.

10. An imageable element, comprising:
a substrate; and
an imageable layer on the substrate,
wherein the imageable layer is formed by coating the negative imaging paste solution of claim 9 on the substrate.

11. A method of producing a printing plate, comprising:
(i) providing the imageable element of claim 10, and defining an imaging area and a non-imaging area on the imageable layer of the imageable element;
(ii) exposing the imageable layer in the imaging area to near infrared radiation in order to form a latent image; and
(iii) after step (ii), contacting the imageable layer with a fountain solution in order to selectively remove the imageable layer in the non-imaging area from the substrate.
